(19) United States
(12) Patent Application Publication
(10) Pub. No.: US 2025/0308842 A1
(43) Pub. Date: Oct. 2, 2025

(54) SEMICONDUCTOR ELECTRICAL INSULATOR WITH REDUCED ARCING

(71) Applicant: Axcelis Technologies, Inc., Beverly, MA (US)

(72) Inventors: Joshua Abeshaus, Beverly, MA (US); Brett Snowden, Beverly, MA (US); Makita Erni, Peabody, MA (US); Joseph Valinski, Beverly, MA (US); Neil Bassom, Beverly, MA (US); Joseph Foley, Beverly, MA (US)

(21) Appl. No.: 19/093,857

(22) Filed: Mar. 28, 2025

Related U.S. Application Data
(60) Provisional application No. 63/573,441, filed on Apr. 2, 2024.

(51) Int. Cl. H01J 37/317; H01J 37/32

(52) U.S. Cl. CPC H01J 37/3171; H01J 37/32568; H01J 2237/0206; H01J 2237/026; H01J 2237/038

(57) ABSTRACT

The system includes an insulative assembly having a first end and a second end opposite to the first end. The insulative assembly includes an insulator body having a plurality of shielding features defined on a surface thereof between the first end and the second end. The plurality of shielding features have a stairstep profile and are spaced apart and overlap with each other. Each space between adjacent shielding features defines a groove having a base and an entrance opposite the base, and a path connecting the base to the entrance may require at least two line segments. The plurality of shielding features and grooves increase the tracking length of the insulative assembly and provide a low enough fluid conductance that conductive deposits do not fully coat the length of the insulative assembly.

### CROSS-REFERENCE TO RELATED APPLICATIONS

This application claims priority to U.S. Provisional Patent Application No. 63/573,441, filed Apr. 2, 2024, the entire disclosure of which is hereby incorporated by reference.

### FIELD OF THE DISCLOSURE

This disclosure relates to ion implantation and, more particularly, to an insulative assembly in an ion implanter.

### BACKGROUND OF THE DISCLOSURE

In the manufacture of semiconductor devices, ion implantation is used to dope semiconductors with impurities. Ion implantation systems are often used to implant a workpiece, such as a semiconductor wafer, with ions from an ion beam to produce n-type or p-type material doping or to form passivation layers during fabrication of an integrated circuit. Such beam treatment can selectively implant the wafers with impurities of a specified dopant material, at a predetermined energy level, and in controlled concentration to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material workpiece, whereas a “p-type” extrinsic material workpiece often results from ions generated with source materials such as boron, gallium, or indium.

A typical ion implanter includes an ion source, an ion extraction device, a mass analysis device, a beam transport device, and a process chamber. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, workpieces are transferred in and out of the process chamber via a workpiece handling system, which may include one or more robotic arms, for placing a workpiece to be treated in front of the ion beam and removing treated workpieces from the ion implanter.

Insulators are used in ion implanters to connect and align components at different electrical potentials while keeping the components electrically isolated from each other. A common electrical breakdown of an insulator in an ion implanter is a flashover arc caused by conductive deposits on the surface of the insulator, which can cause leakage current. For example, several areas within an ion implantation system are negatively biased. A suppression electrode is often used in an ion implanter with an ion source extraction electrode at the exit of an acceleration tube, at an entrance of a deceleration tube, or somewhere else that a positive potential is used. Suppression electrodes will discourage or inhibit electron movement between two areas that the suppression electrode separates. The suppression electrodes are usually mounted on small ceramic standoffs, since its negative potential is not very high and the weight of the electrodes is usually small.

The suppression electrode in the source extraction area is in a hostile environment. First, the high energy, high flux ion beam causes sputtering of electrode and aperture materials (e.g., metal and carbon) to coat unshielded insulative surfaces, which makes these surfaces conductive. In addition, a build-up of conductive “flakes” can cause problems like initiating high voltage sparks. Second, the vacuum environment tends to be a dirty location with respect to particles and contaminants, often containing condensable vapor from within an ion source feed material. The vapor can snake through elaborate shielding structures to coat or deposit on hidden insulative surfaces. Third, related to the two reasons mentioned above, the suppression electrode must endure frequent and high voltage sparks with large energy release (e.g., several Joules). Although typical ceramic standoffs are well protected by layer(s) of metal shields, those high voltage sparks often induce secondary sparks in the hidden insulative areas to cause sputter coating even in those hidden areas. Insulators can crack because of a sudden surge current and rapid heating. Adding to all these damaging environment factors, the electrodes (e.g., suppression and ground electrodes) may be mechanically manipulated in position relative to the ion source, making the situation even more complicated.

### BRIEF SUMMARY OF THE DISCLOSURE

An embodiment of the present disclosure provides a system. The system may include an insulative assembly having a first end and a second end opposite to the first end. The insulative assembly may include an insulator body having a plurality of shielding features defined on a surface thereof between the first end and the second end. The plurality of shielding features may have a stairstep profile and may be spaced apart and overlap with each other. Each space between adjacent shielding features may define a groove having a base and an entrance opposite the base, and a path connecting the base to the entrance may require at least two line segments.

In some embodiments, the system may further comprise a first component at the first end and a second component at the second end. The first component and the second component may be at different potentials.

In some embodiments, the system may further comprise an ion source, a beamline assembly, and an end station that includes a chuck configured to hold a workpiece. The first component may be a suppression electrode of the ion source and the second component is an extraction electrode of the ion source. The ion source may be configured to emit an ion beam directed to the workpiece by the beamline assembly.

In some embodiments, a first hole may be defined in the first end and a second hole may be defined in the second end. The first component may be coupled to the first end and the second component may be coupled to the second end by fasteners received in the first hole and the second hole, respectively.

In some embodiments, the first hole and the second hole may be tapered holes having internal threading configured to engage with the fasteners.

In some embodiments, the insulative assembly may define a texture on a surface of the insulative assembly within the groove.

In some embodiments, the path may require at least three of the line segments.

Another embodiment of the present disclosure provides a system. The system may comprise an insulative assembly having a first end and a second end opposite to the first end. The insulative assembly may comprise a first insulator body defining the first end and a second insulator body coupled to the first insulator body and defining the second end. The first insulator body may include a first central protrusion extending from the first end and a first annular protrusion extending from the first end, surrounding and spaced apart from the first central protrusion. The second insulator body may include a second central protrusion extending from the second end, coupled to the first central protrusion of the first insulator body, and a second annular protrusion extending from the second end, surrounding and spaced apart from the second central protrusion, the first central protrusion, and the first annular protrusion. A space between the second annular protrusion, the first annular protrusion, and the second central protrusion coupled to the first central protrusion may define a groove having a base and an entrance opposite to the base, and a path connecting the base to the entrance requires at least two line segments.

In some embodiments, the system may further comprise a first component at the first end and a second component at the second end. The first component and the second component may be at different potentials.

In some embodiments, the system may further comprise an ion source, a beamline assembly, and an end station that includes a chuck configured to hold a workpiece. The first component may be a suppression electrode of the ion source and the second component is an extraction electrode of the ion source. The ion source may be configured to emit an ion beam directed to the workpiece by the beamline assembly.

In some embodiments, a first hole may be defined in the first end and a second hole may be defined in the second end. The first component may be coupled to the first end and the second component may be coupled to the second end by fasteners received in the first hole and the second hole, respectively.

In some embodiments, the first hole and the second hole may be tapered holes having internal threading configured to engage with the fasteners.

In some embodiments, the insulative assembly may define a texture on a surface of the insulative assembly within the groove.

In some embodiments, the texture may be provided on an interior surface of the second annular protrusion, and the texture may be provided on interior and exterior surfaces of the first annular protrusion.

In some embodiments, the path may require at least three of the line segments.

In some embodiments, the insulative assembly may further comprise a fastener configured to couple the first central protrusion of the first insulator body to the second central protrusion of the second insulator body.

In some embodiments, a seat may be defined in an end surface of the second central protrusion, and a portion of the first central protrusion may be received by the seat.

Another embodiment of the present disclosure provides a method. The method may comprise providing a first insulator body defining a first end. The first insulator body may include a first central protrusion extending from the first end and a first annular protrusion extending from the first end and surrounding and spaced apart from the first central protrusion.

The method may further comprise providing a second insulator body defining a second end. The second insulator body may include a second central protrusion extending from the second end and a second annular protrusion extending from the second end and surrounding and spaced apart from the second central protrusion.

The method may further comprise coupling the first central protrusion of the first insulator body to the second central protrusion of the second insulator body to form an insulative assembly, such that the second annular protrusion further surrounds and is spaced apart from the first central protrusion and the first annular protrusion. A space between the second annular protrusion, the first annular protrusion, and the second central protrusion coupled to the first central protrusion may define a groove having a base and an entrance opposite to the base, and a path connecting the base to the entrance may requires at least two line segments.

In some embodiments, the first insulator body and the second insulator body may be produced by additive manufacturing.

In some embodiments, the method may further comprise directing particles toward the insulative assembly, wherein the particles are part of an ion beam or are sputtered by an ion beam.

### DESCRIPTION OF THE DRAWINGS

For a fuller understanding of the nature and objects of the disclosure, reference should be made to the following detailed description taken in conjunction with the accompanying drawings, in which:

FIG. 1 shows a cross-sectional view of an embodiment of an insulative assembly design;

FIGS. 2 and 3 show cross-sectional views of embodiments of an insulative assembly design;

FIGS. 4-8 show cross-sectional views of embodiments of an insulative assembly design that curves back upon itself;

FIGS. 9-12 show cross-sectional views of embodiments of an insulative assembly design with layered self-shielding features;

FIGS. 13 and 14 show cross-sectional views of embodiments of an insulative assembly design with helical features;

FIGS. 15-18 show cross-sectional views of embodiments of an insulative assembly design with a mesh and lattice structure;

FIGS. 19-22B show cross-sectional views and a related cutaway view of a stairstep pattern;

FIGS. 23 and 24 show a cross-sectional view and related cutaway view of a textured pattern;

FIGS. 25 and 26 show a cross-sectional view and related cutaway view of a byzantine pattern;

FIGS. 27A-27C show cross-sectional views and an exploded view of an insulative assembly according to another embodiment of the present disclosure.

FIG. 28 is a diagram showing an embodiment of a vacuum system in accordance with the present disclosure.

FIG. 29 is a flowchart of a method according to an embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

The insulative assembly can be shaped to maximize the length of the leakage path along the surface from one end to the other, which minimizes flashover arcs. In addition, supplementary self-shielding insulating or conductive convolutions (e.g., grooves) may be added around the insulative assembly to decrease the fluid conductance and, therefore, decrease deposits on the insulative assembly. By utilizing the disclosed layered self-shielding geometry, the length of the leakage path can be increased while decreasing fluid conductance and a total space claim. Such features can include layered self-shielding features, self-shielding features that curve back on themselves, and/or helical paths. The combination of the increased tracking length and the layers of self-shielding can provide a low enough fluid conductance that conductive deposits do not fully coat the length of the insulative assembly. This results in individual unconnected sections with no direct conductive path along the length of the insulative assembly. A lack of direct conductive paths will reduce the probability of arcing across the insulative assembly.

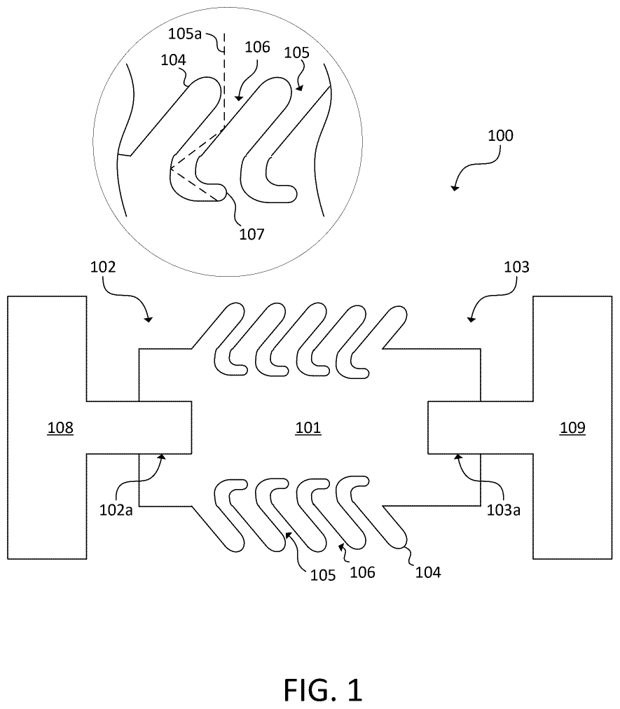

FIG. 1 shows a cross-sectional view of a system 100 with an insulative assembly 101. The insulative assembly 101 can be fabricated of alumina or other materials that are electrically insulating and can withstand high temperatures. In some embodiments, the insulative assembly 101 may be fabricated of quartz. The insulative assembly 101 has a first end 102 and a second end 103. A first component 108 is coupled to the first end 102 and a second component 109 is coupled to the second end 103. In some embodiments, a first hole 102a may be defined in the first end 102, and a second hole 103a may be defined in the second end 103. The first component 108 may be coupled to the first end 102 by a fastener received in the first hole 102a, and the second component 109 may be coupled to the second end 103 by a fastener received in the second hole 103a. In some embodiments, the first hole 102a and the second hole 103a may be tapered holes having threading configured to engage with the fasteners coupling to the first component 108 and the second component 109, respectively. Tapered holes having rounded ends can help avoid cracking and crack propagation under stress from a fastener and during manufacturing. In some embodiments, the first hole 102a and the second hole 103a can aid with printing during additive manufacturing or other manufacturing techniques. The first component 108 and the second component 109 have or can operate at different potentials. In an example, the first component 108 is a suppression electrode and the second component 109 is an extraction electrode. In another example, the first component 108 is an extraction electrode and the second component 109 is a suppression electrode. While the embodiments of the insulative assembly 101 illustrate herein identify the first end 102 and the second end 103 as particular ends of the insulative assembly 101, the ends may be reversed to have the insulative assembly 101 provided in the opposite orientation from what is shown.

The insulative assembly 101 includes an insulator body having shielding features 104 defined on a surface thereof between the first end 102 and the second end 103. The insulative assembly 101 can be formed using additive manufacturing or other manufacturing techniques. Various shapes of the insulative assembly 101 are disclosed herein. These various shapes can be used independently or combined together in an insulative assembly 101.

Spacing between the shielding features 104 can affect operation because the insulators will become coated with a conductive deposit. The spacing should be far enough to prevent arcing after the exposed surfaces are coated. This spacing between shielding features 104 may be approximately 1.4 mm, but other dimensions are possible and this is merely one example. The shielding features may be strong enough to support themselves and a cantilevered plate, but do not typically touch other components. Self-shielding configurations, increased tracking length, surface area, and/or a number of breaks in a potential conductivity path between the shielding features 104 may be used to prevent arcing because these design considerations reduce the possibility of forming a complete circuit between the first component 108 and the second component 109.

A pair of adjacent shielding features 104 define a groove 105 between them. The groove 105 can extend into a body of the insulative assembly 101. Eight grooves 105 are illustrated in FIG. 1, but the number of grooves 105 can vary with the insulative assembly 101. For example, the number of grooves 105 can depend on the dimensions of the insulative assembly 101, the dimensions of the grooves 105, the size or concentration of particles in an environment around the insulative assembly 101, or the electrical properties of the first component 108 and second component 109. While the grooves 105 in FIG. 1 are all illustrated as similar, an insulative assembly 101 can include one or more grooves 105 with different shapes from the others in the insulative assembly 101.

The groove 105 has a base 107. The groove 105 also defines an entrance 106 at an opposite end of the groove 105 from the base 107. The groove 105 can be curved, angled, or other shapes disclosed herein. While not shown in FIG. 1, the groove 105 can fork or have multiple sections that extend in different directions. Thus, the groove 105 can have multiple bases 107. In an instance, the groove 105 can have a single entrance 106 as shown in FIG. 1. A groove 105 also can have multiple entrances 106 connected with a single groove 105.

Embodiments disclosed herein have geometries such that some regions of the surface of the groove 105 are only reachable from the outside of the insulative assembly 101 by chains of line-of-sight trajectories that intercept the insulative assembly 101 surface at a minimum of two other points. For example, a path connecting the base 107 and the entrance 106 requires at least two line segments, as shown in the inset of FIG. 1. The dotted line 105a represents a path of a particle within the groove 105. To reach the base 107 of the groove 105 from the entrance 106, the particle must impact a surface of the groove 105 at least two times in this example. Thus, there are three line segments to reach the base 107. Each impact by a particle against a surface of the groove 105 lessens the likelihood of further transit toward the base 107 of the groove 105. This will reduce the probability of particles forming a film or build-up that covers enough of the surface of the groove 105 or insulative assembly 101 to cause arcing.

While illustrated as only between the shielding features 104, a groove 105 can be otherwise located in the insulative assembly 101. Thus, a groove 105 can be adjacent a single shielding feature 104 instead of between a pair of shielding features 104. Such a groove 105 can be positioned to further reduce the fluid conductance so that conductive deposits do not fully coat the length of the insulative assembly 101.

The insulative assembly 101 can define a texture on a surface of the insulative assembly 101 within the groove 105. The texture may be self-shielding such that each layer offers some shielding from line-of-sight coating to the next layer. The insulative assembly 101 also can define a texture on a surface of the insulative assembly 101 on the shielding feature 104. The texture can prevent particles from impacting multiple surfaces of the groove 105 or insulative assembly 101. Instead, the particle will be more likely to remain fixed on the surface of the shielding feature 104 or insulative assembly 101.

A distance between the first end 102 and the second end 103 can be 10 cm or less. The particular dimensions of the insulative assembly 101 may depend on the electrical properties of the first component 108 and second component 109. For example, the shielding features 104 can have a length from 0.1 mm and 50 mm (e.g., from 0.4 mm to 0.5 mm). An insulative assembly 101 may have an overall length of approximately 50 mm and a diameter of approximately 18 mm. A length of the shielding components 104 can depend on the overall outer diameter, the angle of the shielding components 104, and the strength tolerance of the shielding components 104. A larger tracking length may provide better results. A tracking length of the insulative assembly 101 may correspond to the conductive path between the first end 102 and the second end 103. The shielding features 104 may case the tracking length to be from 100 mm to 220 mm (e.g., 130 mm to 220 mm) based on the tortuous path around each groove 105.

In an instance, arcing can occur between coated sections of the insulative assembly 101 and between a coated section of the insulative assembly 101 and metal shielding cups (not illustrated). Arcing can be controlled by the feature shape (flat, round, sharp, etc.), size (larger rounds reduce may arcing risk), and/or spacing (larger spacing may reduce arcing risk). This is merely one example of a potential arcing risk and other arcing risks are possible.

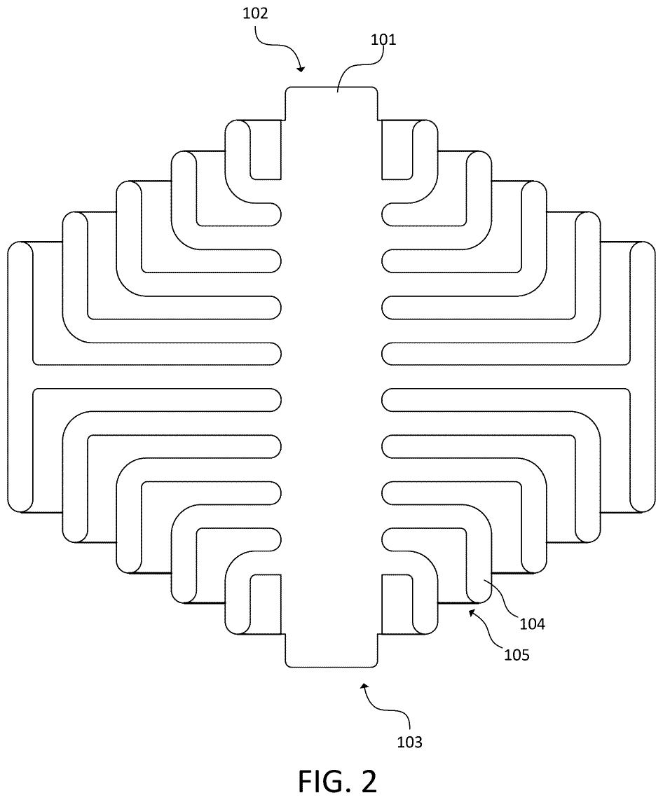

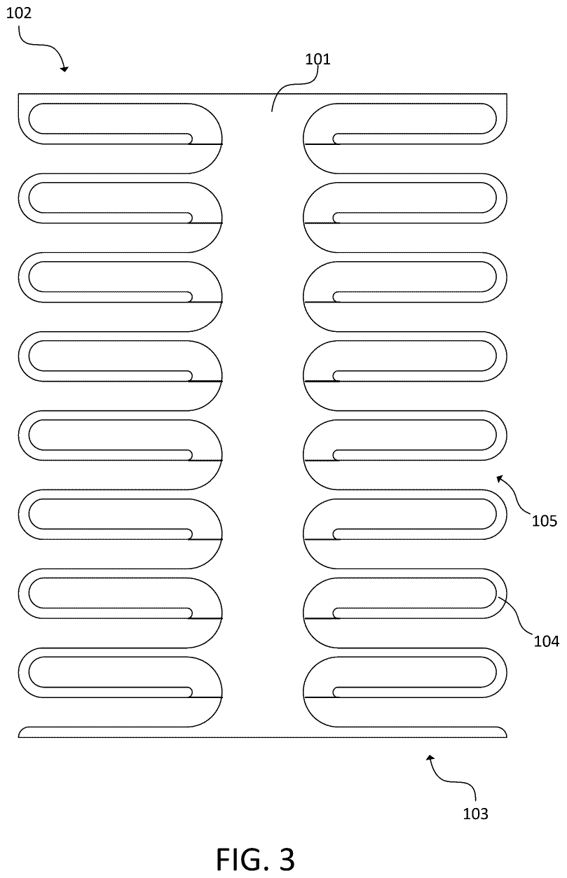

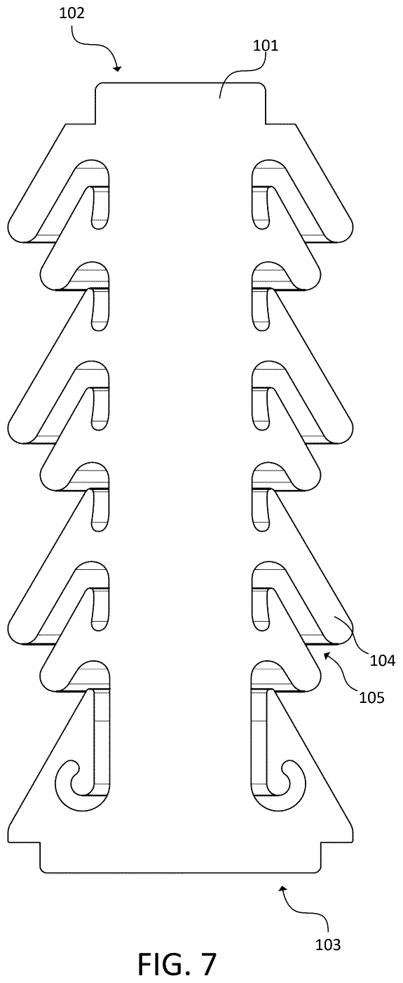

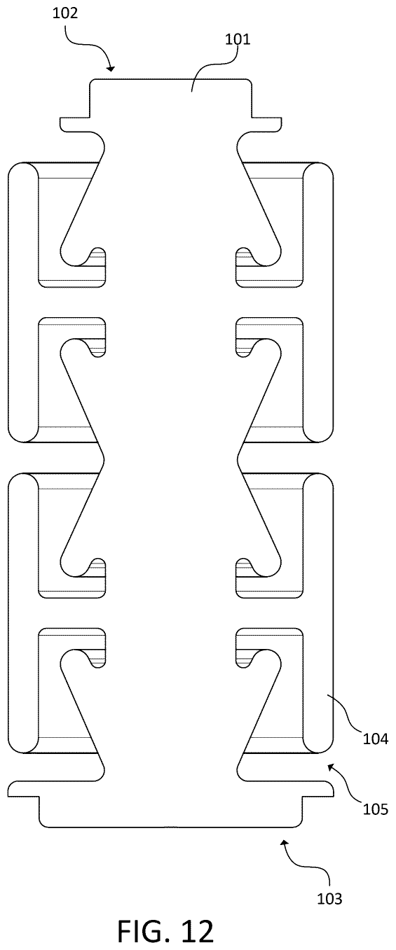

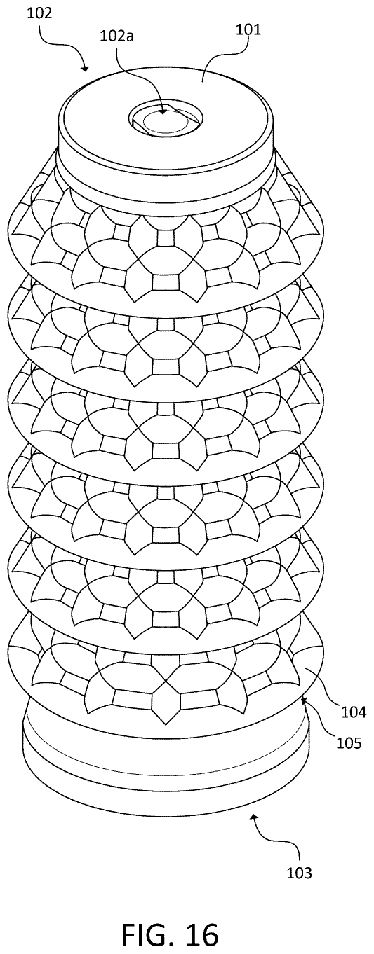

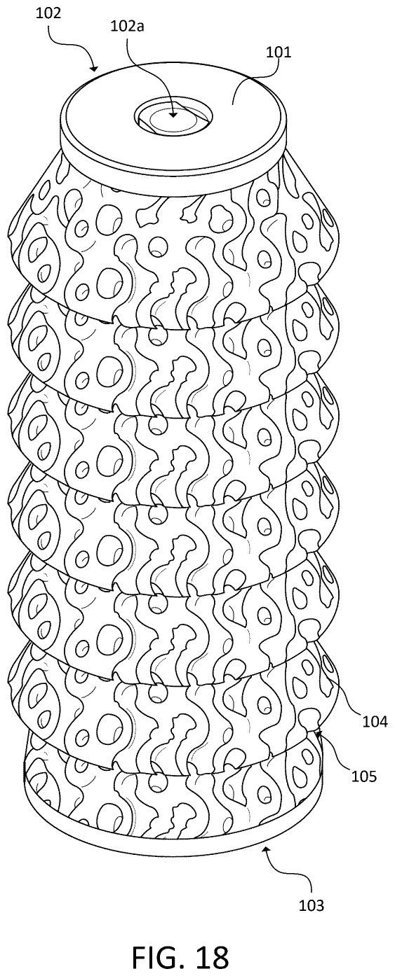

FIGS. 2-26 show various embodiments of the insulative assembly 101. FIGS. 2 and 3 show cross-sectional views of embodiments of an insulative assembly 101. In FIG. 2, the shielding features 104 are angled to form a perpendicular channel 105. The shielding features 104 in FIG. 2 provide layered self-shielding with deep-shielded pockets and a large tracking length. In FIG. 3 the shielding features 104 fold onto themselves, which forms a U-shaped groove 105. The shielded pockets from the shielding features 104 in FIG. 3 provide shielded openings and a large tracking length.

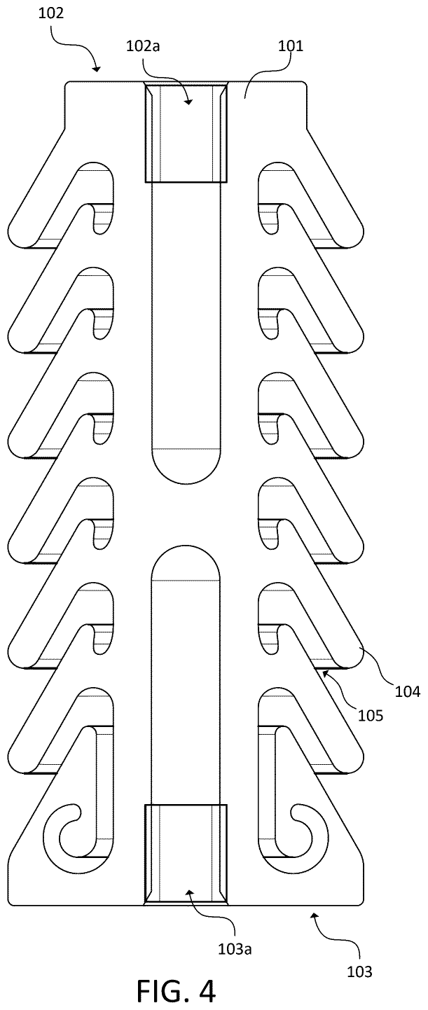

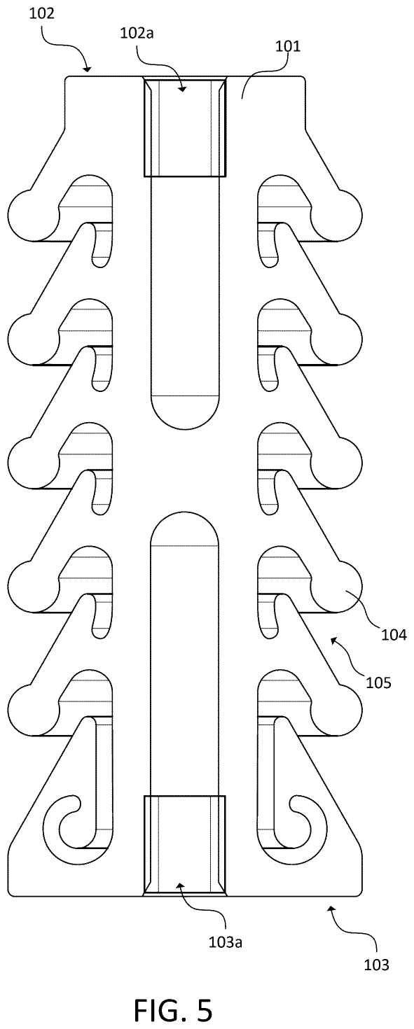

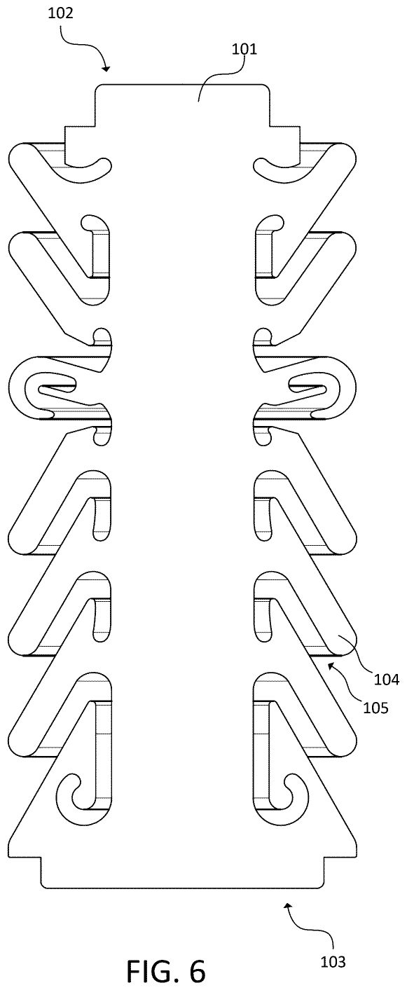

FIGS. 4-8 show cross-sectional views of embodiments of an insulative assembly 101 that curves back upon itself. Similar to FIG. 3, each of the shielding features 104 fold onto themselves. This results in U-shaped grooves 105. Some examples, such as FIGS. 4-7, include multiple U-shaped grooves 105. The curvature of the grooves 105 can further include a circular or spiral pattern. For example, FIG. 4 includes features to increase effectiveness. The shielding features 104 in FIG. 4 curve back on themselves in both the bottom feature of FIG. 4 and other features in FIG. 4. FIG. 5 includes corona balls at the end of the shielding features 104, which can decrease a risk of arcing from the ends of the shielding features 104. In FIG. 6, the shielding features 104 switch orientation between the two opposite ends. As the grooves 105 in the shielding features 104 part way up the insulative assembly 101 switch directions, particles that enter through the grooves 105 are presented with a shielding surface.

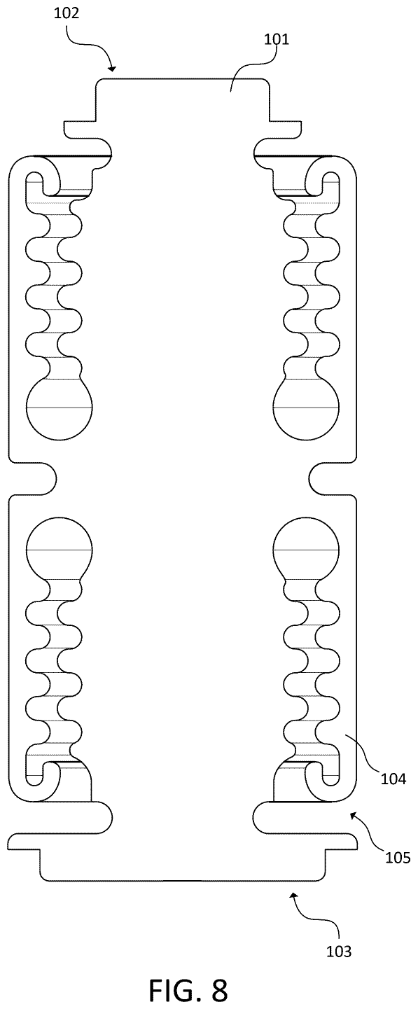

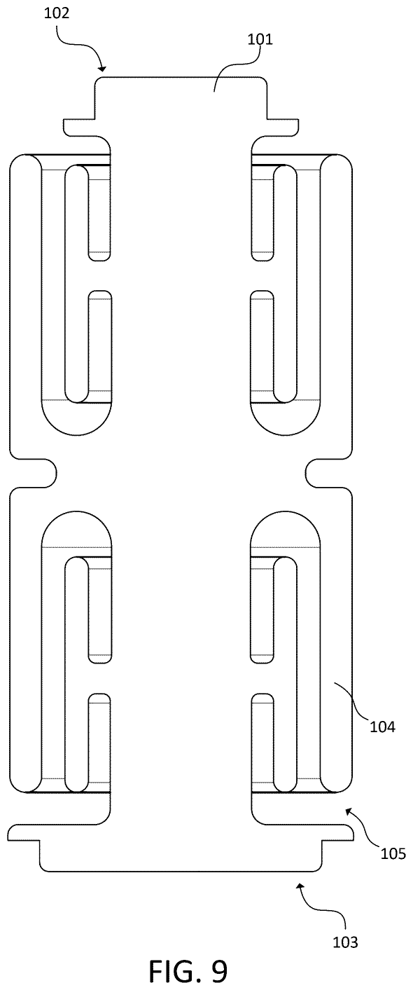

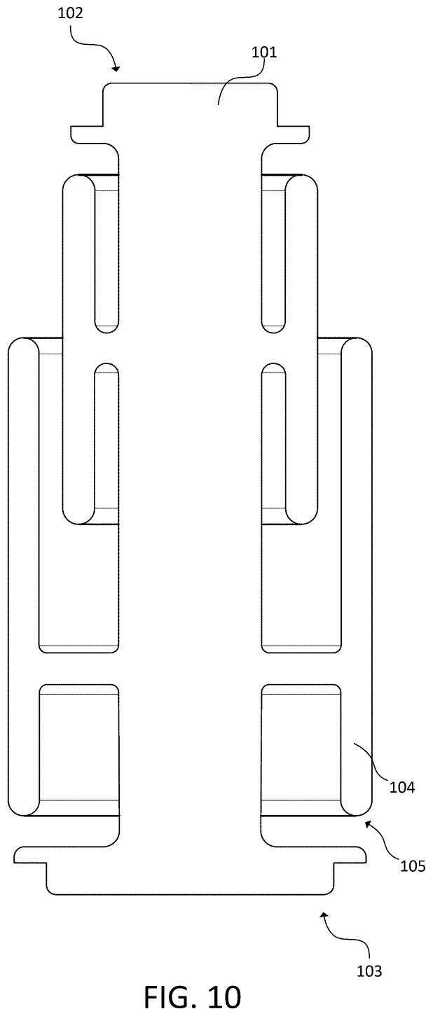

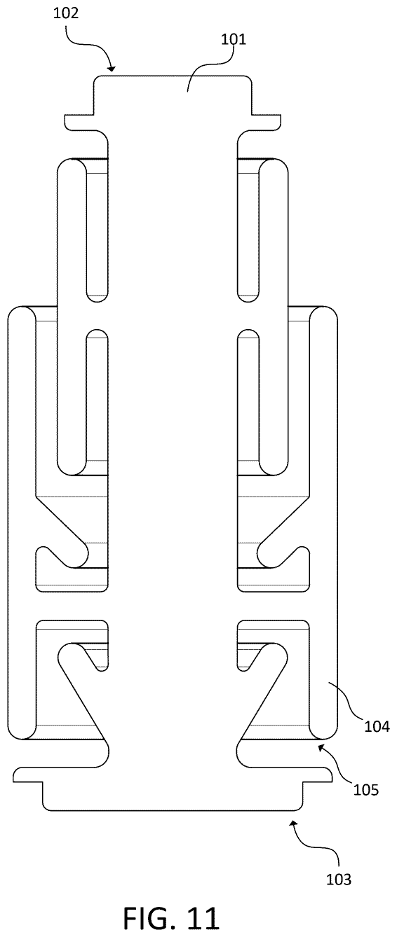

FIGS. 9-12 show cross-sectional views of embodiments of an insulative assembly with layered self-shielding features. Many of the shielding features 104 include angular extensions that form a complex groove 105. In FIG. 9, the grooves 105 provide a more tortuous path than that illustrated in FIG. 8. FIG. 10 includes overlapping cups to decrease the risk of arcing. FIG. 11 adds internal shielding features relative to FIG. 10.

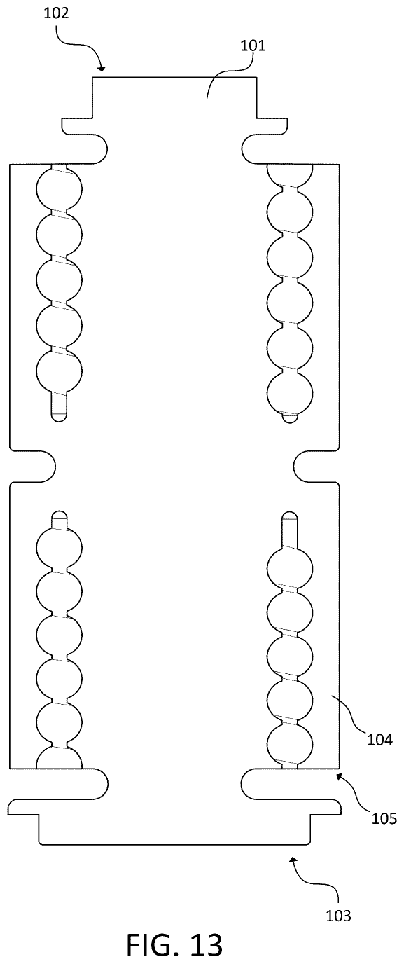

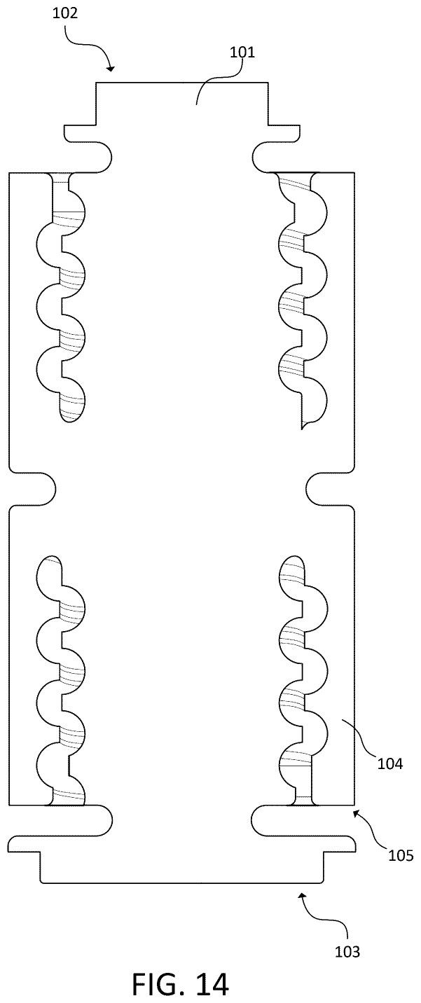

FIGS. 13 and 14 show cross-sectional views of embodiments of an insulative assembly with helical features. The grooves 105 in FIGS. 13 and 14 can be spiral or can be made of concentric spheres. FIG. 13 includes a helical path to increase tracking length and shielding. FIG. 14 includes improved shielding along the helical path as compared to FIG. 13.

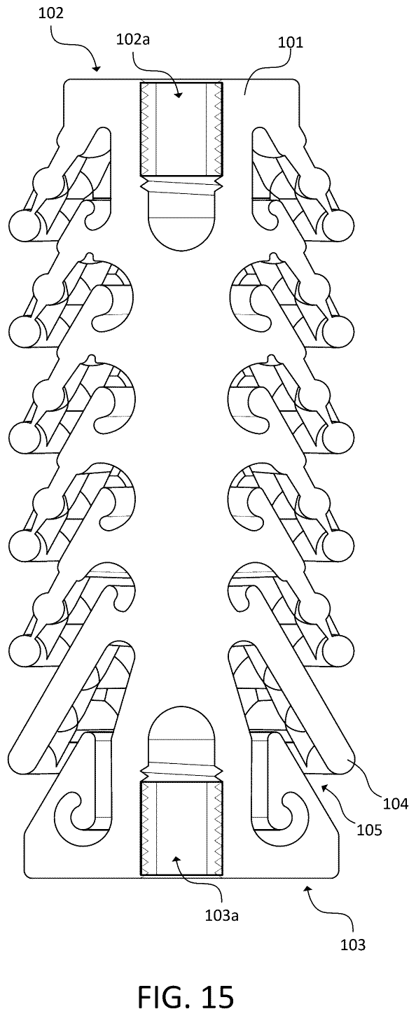

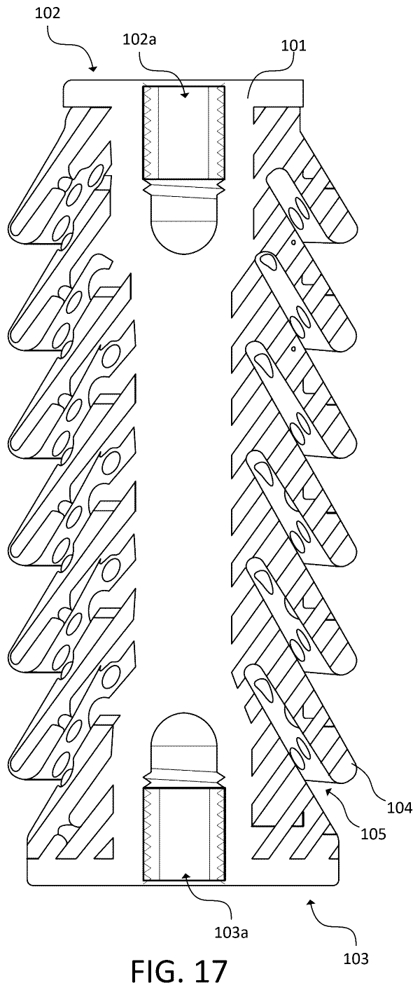

FIGS. 15-18 show cross-sectional views of embodiments of an insulative assembly with a mesh and lattice structure. The shielding features 104 can include one or more holes to form a mesh. This provides extra pathways into the groove 105. These extra pathways can have a complex, non-linear structure within the shielding features 104. For example, FIG. 17 includes a lattice design.

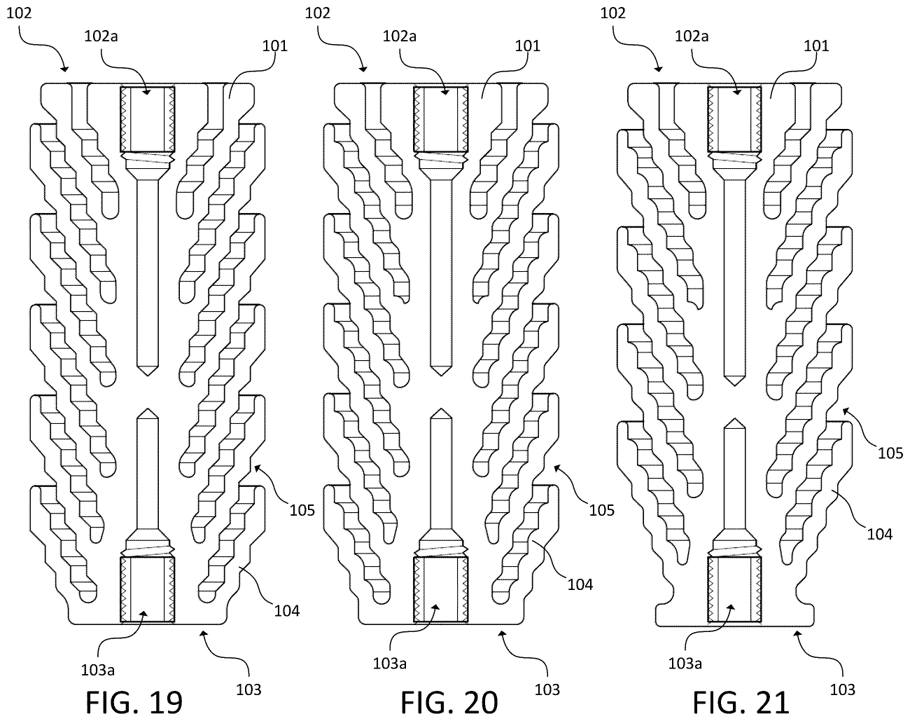

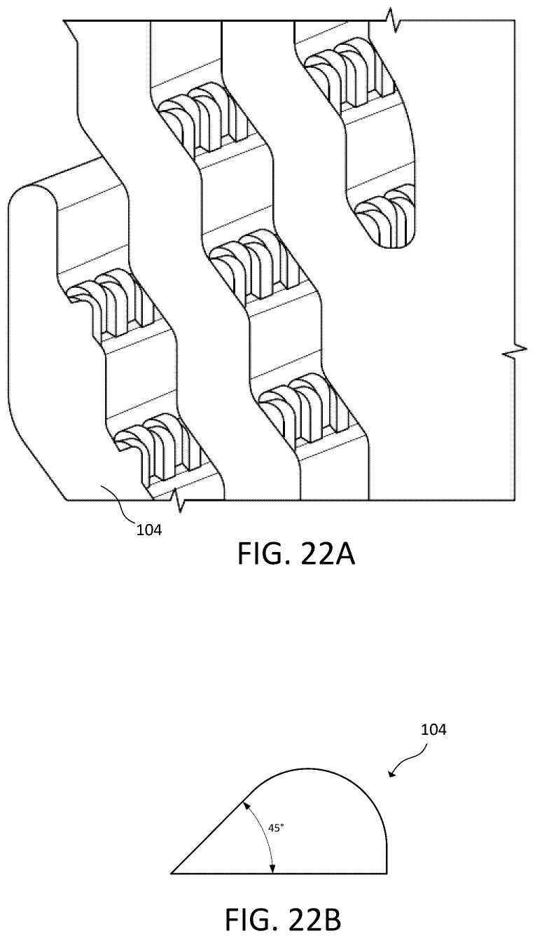

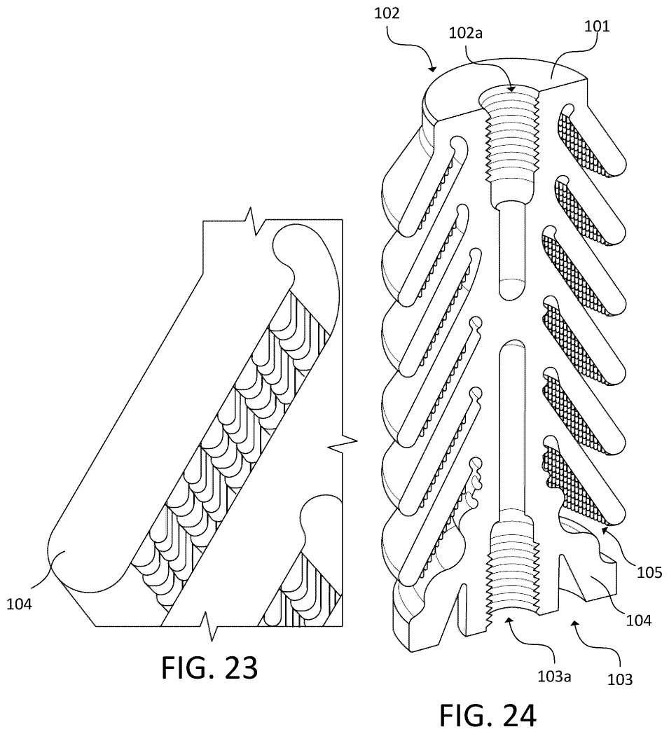

FIGS. 19-21 show cross-sectional views and FIG. 22A shows a related cutaway view of shielding features 104 having stairstep profile and are spaced apart and overlap with each other. The stairstep profile causes the path connecting the base to the entrance of each groove 105 to require at least two line segments, such that a particle entering the groove 105 may bounce at least once. FIGS. 23 and 24 show a cross-sectional view and related cutaway view of a textured pattern. The shielding features 104 define a texture on their surfaces, which are exposed in the groove 105. The shielding features 104 in FIGS. 19-24 also are in the form of a stairstep pattern. The stairstep pattern in FIGS. 19-24 increases surface area, tracking length, and shielding. Texturing can be used to further increase surface area, tracking length, and shielding, as shown in FIG. 22A. The texturing profile, shown in FIG. 22B, may include a 45-degree angle to aid with printability and may be rounded to avoid sharp corners for electrostatics. In some embodiments, the texturing profile may allow particles to more easily bounce out of the groove 105 and prevent particles from bouncing in. Although the texturing is shown on one surface of each stairstep, the texturing may be provided on both surfaces of each stairstep. FIGS. 20 and 21 also include two different gaps between the shielding features 104. The number of “arms” of the shielding features 104 defining the grooves 105 therebetween can vary, depending on the overall length of insulative assembly 101 and the width of the grooves 105. The thickness of the arms may be, for example, 1 mm to 10 mm.

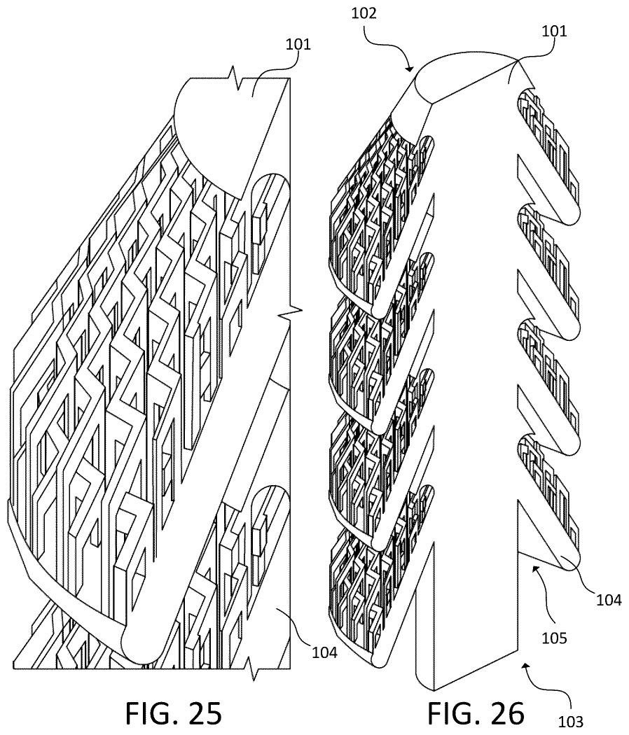

FIGS. 25 and 26 show a cross-sectional view and related cutaway view of a byzantine pattern. The shielding features 104 include an array of sub-features. These sub-features can be linear, angular, or curved. The sub-features can interlock or be arrayed on top of each other to form the shielding features 104 with a byzantine pattern. The embodiments of FIGS. 25 and 26 can include two layers of a stairstep pattern.

There can be external holes on the top and bottom of the illustrated designs that are used for printing during additive manufacturing. These holes can be avoided depending on the design and manufacturing technique.

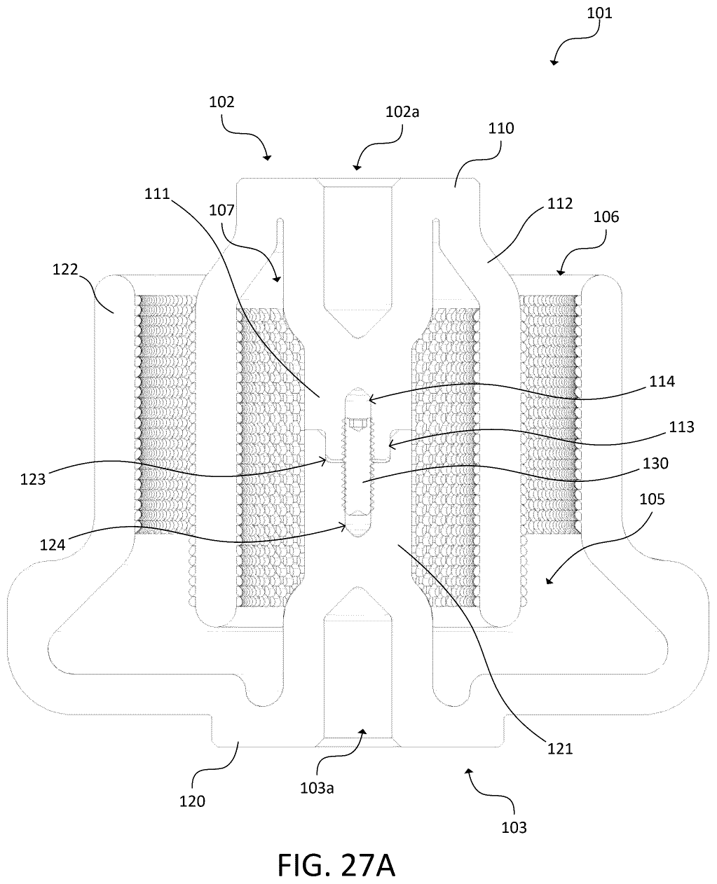

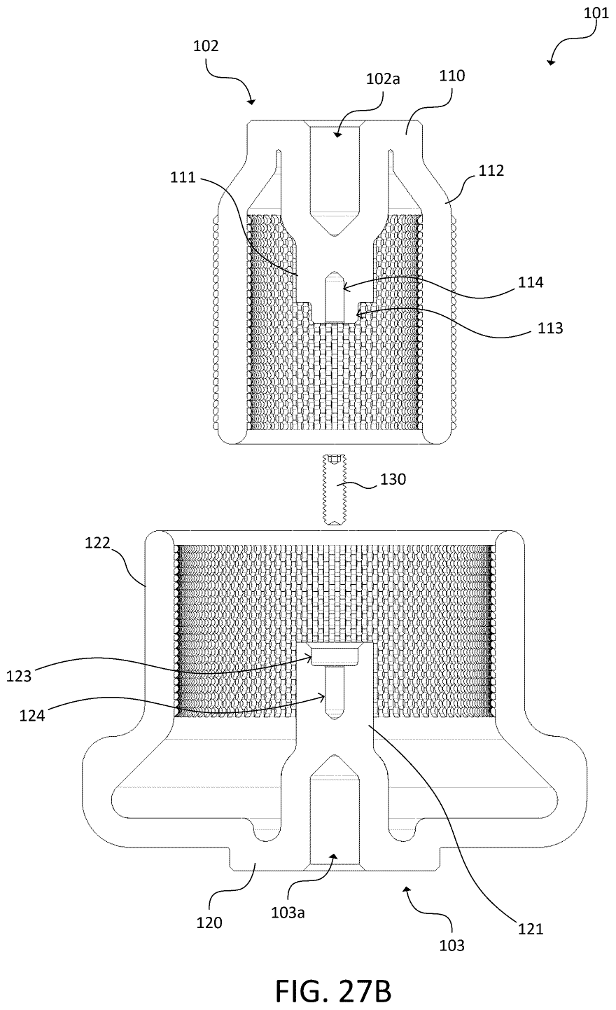

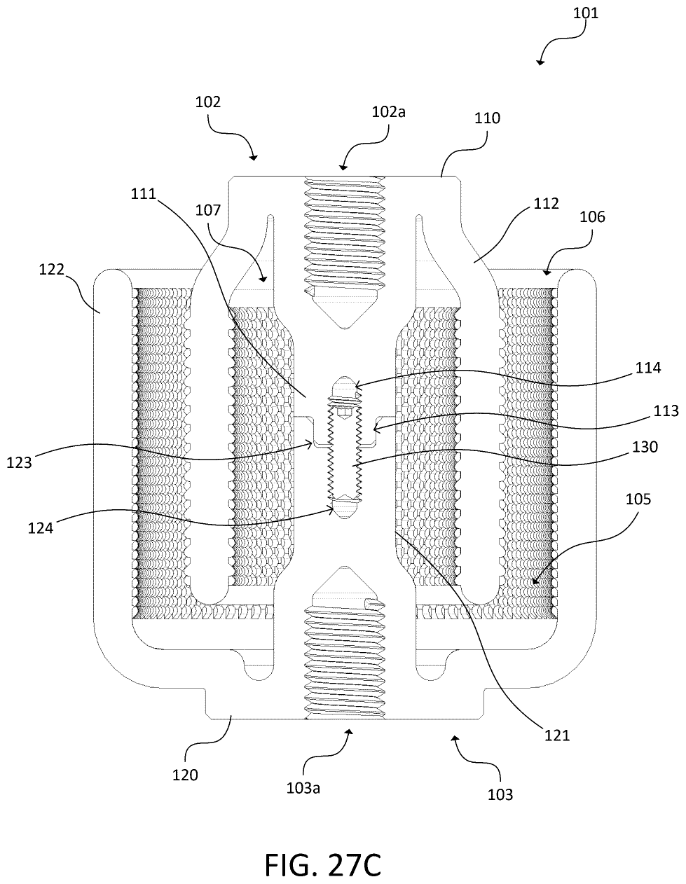

FIGS. 27A-27C illustrate cross-sectional views and an exploded view of an insulative assembly 101 according to another embodiment of the present disclosure having a two-part structure. The insulative assembly 101 comprises a first insulator body 110 defining the first end 102 and a second insulator body 120 defining the second end 103. The second insulator body 120 may be coupled to the first insulator body. The first insulator body 110 includes a first central protrusion 111 extending from the first end 102 and a first annular protrusion 112 extending from the first end 102, surrounding and spaced apart from the first central protrusion 111. The second insulator body 120 includes a second central protrusion 121 extending from the second end 103, coupled to the first central protrusion 111 of the first insulator body 110, and a second annular protrusion 122 extending from the second end 103, surrounding and spaced apart from the second central protrusion 121, the first central protrusion 111, and the first annular protrusion 112. The shapes of the first insulator body 110 and the second insulator body 120 may be defined to aid in manufacturability (e.g., printability by additive manufacturing). For example, the first insulator body 110 and the second insulator body 120 may have consistent wall thicknesses, which can reduce the risk of cracking during post-print de-binding and sintering. The wall thickness may depend on the constraints of the manufacturing process and is not limited herein.

A space between the second annular protrusion 122, the first annular protrusion 112, and the second central protrusion 121 coupled to the first central protrusion 111 may define the groove 105 having a base 107 and an entrance 106 opposite to the base 107. A path connecting the base 107 to the entrance 106 may require at least two line segments. In some embodiments, the path may require at least three of the line segments. The arrangement and shape of the first insulator body 110 and the second insulator body 120 may help catch particles and prevent them from coating deeper into the insulative assembly 101. For example, a portion of the groove 105 at the base of the second annular protrusion 122 may flare out and widen to provide more surface area to collect particles before the path changes direction along the interior of the first annular protrusion 112, as shown in FIG. 27A and FIG. 27B. Alternatively, the portion of the groove 105 at the base of the second annular protrusion 122 may have a consistent thickness, as shown in FIG. 27C.

A texture may be defined on a surface of the insulative assembly 101 within the groove 105. The texture shown in FIGS. 27A-27C may have the same profile as shown in FIG. 22B. For example, the texture may be provided on an interior surface of the second annular protrusion 122, and the texture may be provided on interior and exterior surfaces of the first annular protrusion 112, as shown in FIGS. 27A-27C. Compared to FIG. 27A, the shape of the second annular protrusion 122 may have additional texture provided on the interior surface. In some embodiments, the texture may be provided on other surfaces of the insulative assembly 101. For example, the texture may be provided on an exterior surface of the second annular protrusion 122 or on the angled surfaces of the first annular protrusion 112. In some embodiments, texture may not be present on the first central protrusion 111 or the second central protrusion 121 to avoid crack initiation sites that could compromise the structural integrity of the insulative assembly 101. Texture may also not be present on various surfaces that would decrease the printability of the parts (e.g., the angled surfaces of the second annular protrusion 122). The texture may include features having a radius of about 0.1 mm to about 2 mm. In an instance, the radius of the features may be about 0.4 mm. In some embodiments, smaller features may be possible, having a radius less than 0.1 mm (e.g., less than 50 μm, or as small as about 5 μm).

In some embodiments, the insulative assembly 101 may further comprise a fastener 130 configured to couple the first central protrusion 111 of the first insulator body 110 to the second central protrusion 121 of the second insulator body 120. The fastener 130 may be, for example, a set screw. The fastener 130 may be a conductor (i.e., configured to facilitate conductance between the connected first insulator body 110 and the second insulator body 120) or an insulator (i.e., configured to inhibit conductance between the connected first insulator body 110 and the second insulator body 120). The fastener 130 may be made of any metallic or ceramic material. In an instance, the fastener 130 may be made of stainless steel.

In some embodiments, the first insulator body 110 and the second insulator body 120 may include mating features for alignment of the first central protrusion 111 and the second central protrusion 121 to aid with their assembly. For example, the second central protrusion 121 may include a seat 123 defined in an end surface thereof, and a portion 113 of the first central protrusion 111 may be received by the seat 123. Alternatively, the first central protrusion may include a seat, and a portion of the second central protrusion 121 may be received by the seat. In some embodiments, the mating features may include threading, such that the first central protrusion 111 and the second central protrusion 121 can be coupled together without a separate fastener 130.

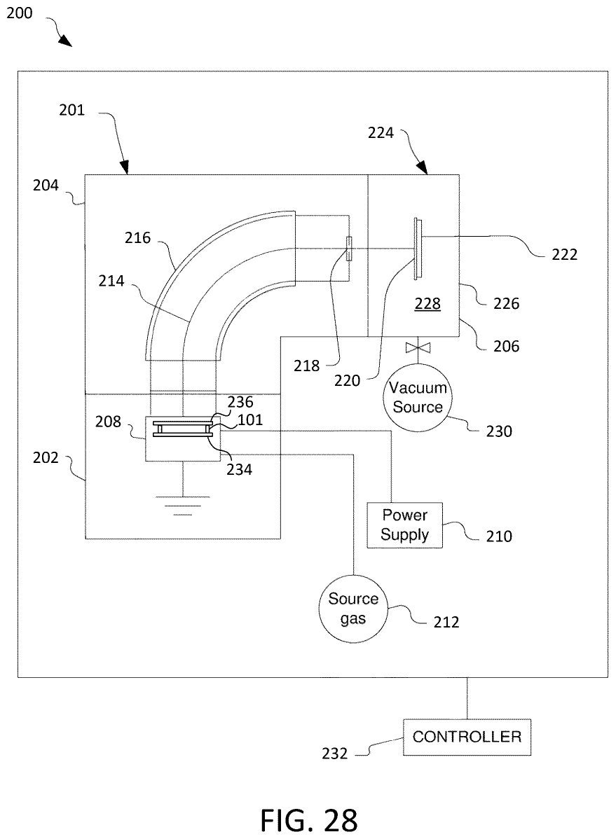

FIG. 28 illustrates an exemplified vacuum system 200 that may implement various apparatus, systems, and methods of the present disclosure. The vacuum system 200 includes an ion implantation system 201, however various other types of vacuum systems are also contemplated, such as plasma processing systems or other semiconductor processing systems. The ion implantation system 201, for example, comprises a terminal 202, a beamline assembly 204, and an end station 206.

Generally speaking, an ion source 208 in the terminal 202 is coupled to a power supply 210, whereby a gas from a gas source 212 (also called a dopant gas) supplied thereto and/or material from a target is ionized into a plurality of ions to form an ion beam 214 (such as ion beam 214). The ion beam 214 is directed through a beam-steering apparatus 216 and out an aperture 218 toward the end station 206. In the end station 206, the ion beam 214 bombards a workpiece 220 (e.g., a semiconductor such as a silicon wafer, a display panel, etc.), which is selectively clamped or mounted to a chuck 222 (e.g., an electrostatic chuck). Once embedded into the lattice of the workpiece 220, the implanted ions change the physical and/or chemical properties of the workpiece 220. Because of this, ion implantation is used in semiconductor device fabrication and in metal finishing, as well as various applications in materials science research.

The ion beam 214 of the present disclosure can take any form, such as a pencil or spot beam, a ribbon beam, a scanned beam, or any other form in which ions are directed toward end station 206, and all such forms are contemplated as falling within the scope of the disclosure.

The end station 206 includes a process chamber 224, such as a vacuum chamber 226, wherein a process environment 228 is associated with the process chamber. The process environment 228 within the process chamber 224, for example, comprises a vacuum produced by a vacuum source 230 (e.g., a vacuum pump) coupled to the process chamber 224 and configured to substantially evacuate the process chamber 224. A controller 232 is provided for overall control of the vacuum system 200.

The embodiments of the present disclosure also may be implemented in various semiconductor processing equipment such as chemical vapor deposition (CVD), physical vapor deposition (PVD), metal organic chemical vapor deposition (MOCVD), etching equipment, and various other semiconductor processing equipment, and all such implementations are contemplated as falling within the scope of the present disclosure.

The ion source 208 (also called an ion source chamber), for example, can be constructed using refractory metals (W, Mo, Ta, etc.) and graphite in order to provide suitable high temperature performance, whereby such materials are generally accepted by semiconductor manufacturers. The gas from the gas source 212 is used within the ion source 208. The gas may or may not be conductive in nature.

FIG. 28 shows the insulative assembly 101 is disposed between a suppression electrode 234 and an extraction electrode 236 in the ion source 208. While shown in the ion source 208, the insulative assembly 101 can be positioned elsewhere in the ion implantation system 201. In an embodiment, particles (e.g., boron, tungsten, fluorine, and/or carbon) surround or are proximate the insulative assembly 101. The particles can be part of the ion beam 214 or can be sputtered by the ion beam 214, though other sources are possible. The insulative assembly 101 can be any of the embodiments disclosed herein. The particles can deposit on the insulative assembly 101, but the resulting film of the particles is separated from itself by grooves 105 in the insulative assembly 101 as shown in at least FIG. 1. While disclosed between the suppression electrode 234 and an extraction electrode 236, the insulative assembly 101 also can be disposed between the suppression electrode 234 and a ground electrode (not illustrated). The insulative assembly 101 also can be part of a filter or other optics in the ion implantation system 201.

The insulative assembly 101 can be a disposable or replaceable part. For example, the current flow between the suppression electrode 234 and the extraction electrode 236 usually increases over time as particles land on the insulative assembly 101. The insulative assembly 101 can be replaced when the current exceeds a threshold or the resistance across the insulative assembly 101 is below a threshold. Embodiments of the insulative assembly 101 disclosed herein can increase the amount of time between such replacements because direct conductive paths for the particles on the insulative assembly 101 are impeded or minimized.

Embodiments of the target body disclosed herein can be formed using machining, chemical etching, and/or additive manufacturing. Additive manufacturing processes are available for many materials used in the insulative assembly 101, such as alumina.

The insulative assemblies 101 disclosed herein are merely examples of possible designs that could be used with a high number of sections and a low fluid conductance pathway. Other designs of the insulative assembly 101 can meet the geometric characteristics defined here.

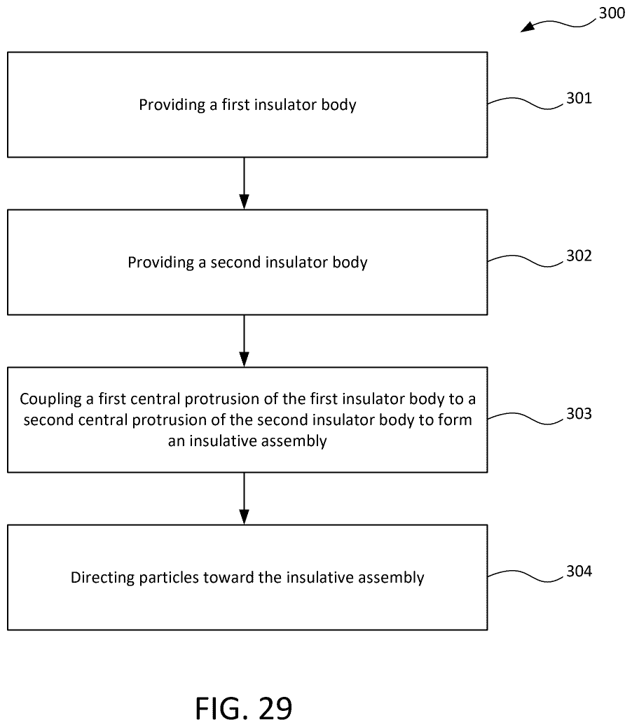

Another embodiment of the present disclosure provides a method 300, as shown in FIG. 29. The method 300 may utilize the insulative assembly 101 according to the embodiments described in connection with FIGS. 27A-C.

At step 301, a first insulator body is provided. The first insulator body may define a first end. The first insulator body may include a first central protrusion extending from the first end and a first annular protrusion extending from the first end and surrounding and spaced apart from the first central protrusion.

At step 302, a second insulator body is provided. The second insulator body may define a second end. The second insulator body may include a second central protrusion extending from the second end and a second annular protrusion extending from the second end and surrounding and spaced apart from the second central protrusion.

The first insulator body and the second insulator body may be produced by additive manufacturing. By producing each insulator body separately, the manufacturability of the features of each insulator body (e.g., the central protrusion and the annular protrusion) may be improved compared to the feasibility of producing the same structure as a monolithic component.

At step 303, the first central protrusion of the first insulator body is coupled to the second central protrusion of the second insulator body to form an insulative assembly, such that the second annular protrusion further surrounds and is spaced apart from the first central protrusion and the first annular protrusion. In some embodiments, the first central protrusion may be coupled to the second central protrusion by a fastener. In some embodiments, the first central protrusion and the second central protrusion may include mating features (e.g., a seat configured to receive a portion of the other component) for alignment of the first insulator body and the second insulator body when coupling. A space between the second annular protrusion, the first annular protrusion, and the second central protrusion coupled to the first central protrusion may define a groove having a base and an entrance opposite to the base, and a path connecting the base to the entrance requires at least two line segments.

While steps 301 to 303 of the method 300 is described in connection with the two-part structure of the insulative assembly shown in FIGS. 27A-C, these steps may be replaced with a step of providing an insulative assembly (i.e., a single monolithic part) according to any other embodiments described herein.

The method 300 may further comprise step 304. At step 304, particles are directed toward the insulative assembly. The particles may be part of an ion beam or may be sputtered by an ion beam. The particles may include boron, tungsten, fluorine, and/or carbon. The particles directed toward the insulative assembly may deposit onto the surface of the insulative assembly in a film, which is separated by the grooves. The number of line segments that define the path from the entrance to the base of each groove can further decrease deposits in the insulative assembly.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an insulative assembly having a first end and a second end opposite to the first end, wherein the insulative assembly includes:
an insulator body having a plurality of shielding features defined on a surface thereof between the first end and the second end, wherein the plurality of shielding features have a stairstep profile and are spaced apart and overlap with each other;
wherein each space between adjacent shielding features defines a groove having a base and an entrance opposite the base, and a path connecting the base to the entrance requires at least two line segments.

2. The system of claim 1, further comprising a first component coupled to the first end and a second component coupled to the second end, wherein the first component and the second component are at different potentials.

3. The system of claim 2, further comprising:
an ion source;
a beamline assembly; and
an end station that includes a chuck configured to hold a workpiece;
wherein the first component is a suppression electrode of the ion source and the second component is an extraction electrode of the ion source, and the ion source is configured to emit an ion beam directed to the workpiece by the beamline assembly.

4. The system of claim 2, wherein a first hole is defined in the first end and a second hole is defined in the second end, the first component being coupled to the first end and the second component being coupled to the second end by fasteners received in the first hole and the second hole, respectively.

5. The system of claim 4, wherein the first hole and the second hole are tapered holes having internal threading configured to engage with the fasteners.

6. The system of claim 1, wherein the insulative assembly defines a texture on a surface of the insulative assembly within the groove.

7. The system of claim 1, wherein the path requires at least three of the line segments.

8. A system comprising:
an insulative assembly having a first end and a second end opposite to the first end, wherein the insulative assembly comprises:
a first insulator body defining the first end, wherein the first insulator body includes a first central protrusion extending from the first end and a first annular protrusion extending from the first end, surrounding and spaced apart from the first central protrusion; and
a second insulator body coupled to the first insulator body and defining the second end, wherein the second insulator body includes a second central protrusion extending from the second end, coupled to the first central protrusion of the first insulator body, and a second annular protrusion extending from the second end, surrounding and spaced apart from the second central protrusion, the first central protrusion, and the first annular protrusion;
wherein a space between the second annular protrusion, the first annular protrusion, and the second central protrusion coupled to the first central protrusion defines a groove having a base and an entrance opposite to the base, and a path connecting the base to the entrance requires at least two line segments.

9. The system of claim 8, further comprising a first component at the first end and a second component at the second end, wherein the first component and the second component are at different potentials.

10. The system of claim 9, further comprising:
an ion source;
a beamline assembly; and
an end station that includes a chuck configured to hold a workpiece;
wherein the first component is a suppression electrode of the ion source and the second component is an extraction electrode of the ion source, and the ion source is configured to emit an ion beam directed to the workpiece by the beamline assembly.

11. The system of claim 9, wherein a first hole is defined in the first end and a second hole is defined in the second end, the first component being coupled to the first end and the second component being coupled to the second end by fasteners received in the first hole and the second hole, respectively.

12. The system of claim 11, wherein the first hole and the second hole are tapered holes having internal threading configured to engage with the fasteners.

13. The system of claim 8, wherein the insulative assembly defines a texture on a surface of the insulative assembly within the groove.

14. The system of claim 13, wherein the texture is provided on an interior surface of the second annular protrusion, and the texture is provided on interior and exterior surfaces of the first annular protrusion.

15. The system of claim 8, wherein the path requires at least three of the line segments.

16. The system of claim 8, wherein the insulative assembly further comprises a fastener configured to couple the first central protrusion of the first insulator body to the second central protrusion of the second insulator body.

17. The system of claim 8, wherein a seat is defined in an end surface of the second central protrusion, and a portion of the first central protrusion is received by the seat.

18. A method comprising:
providing a first insulator body defining a first end, wherein the first insulator body includes a first central protrusion extending from the first end and a first annular protrusion extending from the first end and surrounding and spaced apart from the first central protrusion;
providing a second insulator body defining a second end, wherein the second insulator body includes a second central protrusion extending from the second end and a second annular protrusion extending from the second end and surrounding and spaced apart from the second central protrusion; and
coupling the first central protrusion of the first insulator body to the second central protrusion of the second insulator body to form an insulative assembly, such that the second annular protrusion further surrounds and is spaced apart from the first central protrusion and the first annular protrusion, wherein a space between the second annular protrusion, the first annular protrusion, and the second central protrusion coupled to the first central protrusion defines a groove having a base and an entrance opposite to the base, and a path connecting the base to the entrance requires at least two line segments.

19. The method of claim 18, wherein the first insulator body and the second insulator body are produced by additive manufacturing.

20. The method of claim 18, further comprising:
directing particles toward the insulative assembly, wherein the particles are part of an ion beam or are sputtered by an ion beam.
